(19) United States
(12) Patent Application Publication
(10) Pub. No.: US 2026/0362879 A1
(43) Pub. Date: Nov. 12, 2026

(54) DISPLAY DEVICE COMPRISING SEMICONDUCTOR LIGHT-EMITTING ELEMENT

(71) Applicants: LG ELECTRONICS INC., Seoul (KR); LG DISPLAY CO., LTD., Seoul (KR)

(72) Inventor: Jinhyeok CHOI, Seoul (KR)

(73) Assignees: LG ELECTRONICS INC., Seoul (KR); LG DISPLAY CO., LTD., Seoul (KR)

(21) Appl. No.: 19/120,148

(22) PCT Filed: Oct. 11, 2022
(86) PCT No.: PCT/KR2022/015276

§ 371 Date: Apr. 10, 2025

(51) Int. Cl. H10H 29/49; H10H 20/831; H10H 20/84; H10H 20/858; H10H 29/01

(52) U.S. Cl. CPC H10H 29/49; H10H 20/831; H10H 20/84; H10H 20/8582; H10H 29/012

(57) ABSTRACT

The embodiment relates to a display device including a semiconductor light emitting device. A display device having a semiconductor light emitting device according to the embodiment may include a substrate, a first electrode and a second electrode which are disposed on the substrate and spaced apart from each other, a first insulating layer disposed on the first and second electrodes, an assembly partition wall including a predetermined assembly hole and disposed on the first insulating layer, a semiconductor light emitting device disposed in the assembly hole, a side wiring electrically connected to the side of the semiconductor light emitting device, and a second panel electrode electrically connected to the upper side of the semiconductor light emitting device. The semiconductor light emitting device may include a light emitting structure and a heat transferring insulating layer disposed on the outside of the light emitting structure.

### TECHNICAL FIELD

The embodiment relates to a display device including a semiconductor light emitting device.

### BACKGROUND ART

Large-area displays include liquid crystal displays (LCDs), OLED displays, and micro-LED displays.

A micro-LED display is a display that uses micro-LEDs, semiconductor light emitting devices having a diameter or cross-sectional area of 100 μm or less, as display elements.

Since a micro-LED display uses micro-LEDs, semiconductor light emitting devices, as display elements, it has excellent performance in many characteristics such as contrast ratio, response speed, color reproducibility, viewing angle, brightness, resolution, lifespan, luminous efficiency, or luminance.

In particular, a micro-LED display has the advantage of being able to freely adjust the size or resolution by separating and combining the screen in a modular manner, and the advantage of being able to implement a flexible display.

However, since large micro-LED displays require millions or more micro-LEDs, there is a technical problem in quickly and accurately transferring micro-LEDs to the display panel.

Transfer technologies that are being developed recently include the pick and place process, the laser lift-off method, or the self-assembly method.

Among these, the self-assembly method is a method in which semiconductor light emitting devices find their own assembly positions in a fluid, which is advantageous for implementing large-screen display devices.

Recently, U.S. Pat. No. 9,825,202 and others have presented micro-LED structures suitable for self-assembly, but research on technologies for manufacturing displays through self-assembly of micro-LEDs is still insufficient.

In particular, in the case of rapidly transferring millions or more semiconductor light emitting devices to a large display in the prior art, the transfer speed can be improved, but there is a technical problem that the transfer error rate can increase, which lowers the transfer yield.

In the related technology, a self-assembly transfer process using dielectrophoresis (DEP) is being attempted, but there is a problem that the self-assembly rate is low due to the non-uniformity of the DEP force.

Meanwhile, according to the undisclosed internal technology, DEP force is required for self-assembly, but there is a problem that the semiconductor light emitting devices are not in the correct position in the assembly hole when assembling using self-assembly due to the difficulty in uniformly controlling the DEP force.

In addition, due to this phenomenon of the semiconductor light emitting devices being swayed, there is a problem that the electrical contact characteristics are deteriorated in the subsequent electrical contact process, which lowers the lighting rate.

Therefore, according to the non-public internal technology, DEP Force is required for self-assembly, but when using DEP Force, it faces a technical contradiction in that the electrical contact characteristics are deteriorated due to the phenomenon of the semiconductor light emitting device being biased.

Meanwhile, the internal technology is studying the side wiring technology that connects the panel wiring to the side of the light emitting device chip after self-assembly using DEP force. However, there is a problem in that the wiring is disconnected at the bottom edge of the light emitting device chip in the side wiring process of the internal technology.

In addition, when the electrode process of the panel unit is performed after assembly using DEP force in the internal technology, the power is cut off to the assembly electrode, and when there is no DEP force, the fixing force between the semiconductor light emitting device and the dielectric layer on the assembly electrode is weak, causing the semiconductor light emitting device assembled in the assembly hole to fall off.

### DISCLOSURE

### Technical Problem

One of the technical objects of the embodiment is to solve the problem in which the electrical contact characteristics between the electrode of the self-assembled light emitting device and the electrode of a certain panel are deteriorated, resulting in a lower lighting rate.

In addition, one of the technical objects of the embodiment is to solve the problem of short circuits occurring at the lower edge of the light emitting device chip in the side wiring technology that connects the panel wiring to the side of the light emitting device chip after self-assembly with DEP force in the internal technology.

In addition, one of the technical objects of the embodiment is to solve the problem of the semiconductor light emitting device assembled in the assembly hole being detached due to weak fixing force between the semiconductor light emitting device and the dielectric layer on the assembly electrode when the power is cut off to the assembly electrode after self-assembly in the internal technology and there is no DEP force.

The technical objects of the embodiment are not limited to those described in this item, and include those that can be understood throughout the specification.

### Technical Solution

A display device having a semiconductor light emitting device according to an embodiment may include a substrate, a first electrode and a second electrode spaced apart from each other on the substrate, a first insulating layer disposed on the first and second electrodes, an assembly partition wall having a predetermined assembly hole and disposed on the first insulating layer, a semiconductor light emitting device disposed in the assembly hole, a side wiring electrically connected to a side of the semiconductor light emitting device, and a second panel electrode electrically connected to an upper side of the semiconductor light emitting device.

The semiconductor light emitting device may include a light emitting structure and a heat transferring insulating layer disposed on an outer surface of the light emitting structure.

The light emitting structure may include a first conductivity type semiconductor layer, a second conductivity type semiconductor layer, and an active layer disposed therebetween, and the side wiring may be electrically connected to the first conductivity type semiconductor layer of the semiconductor light emitting device.

The side wiring may include a first side wiring disposed on a side of the semiconductor light emitting device and a second side wiring electrically contacting at least one of the first and second electrodes.

The embodiment further includes a passivation layer disposed between the light emitting structure and the heat transferring insulating layer, and the heat transferring efficiency of the passivation layer may be lower than that of the heat transferring insulating layer.

The side wiring may be disposed on the side of the light emitting structure and the heat transferring insulating layer.

In addition, a display device having a semiconductor light emitting device according to the embodiment may include a substrate, a first electrode and a second electrode disposed to be spaced apart from each other on the substrate, a first insulating layer disposed on the first and second electrodes, an assembly partition formed on the first insulating layer and including a predetermined assembly hole, and a semiconductor light emitting device disposed within the assembly hole.

The semiconductor light emitting device includes a light emitting structure and a heat transferring insulating layer disposed outside the light emitting structure, and a lower end of the heat transferring insulating layer may be disposed to extend to a lower end of the light emitting structure.

The light emitting structure includes a first conductivity type semiconductor layer, a second conductivity type semiconductor layer, and an active layer disposed therebetween, and the side wiring may be electrically connected to the first conductivity type semiconductor layer of the semiconductor light emitting device.

The side wiring may include a first side wiring disposed on a side of the semiconductor light emitting device and a second side wiring electrically contacting at least one of the first and second electrodes.

The embodiment further includes a passivation layer disposed between the light emitting structure and the heat transferring insulating layer, and the heat transferring efficiency of the passivation layer may be lower than that of the heat transferring insulating layer.

The side wiring may be disposed on the side of the light emitting structure and the heat transferring insulating layer.

### Advantageous Effects

According to the display device including the semiconductor light emitting device according to the embodiment, the electrical contact area can be expanded by the side wiring connected to the side of the semiconductor light emitting device, thereby improving the electrical contact characteristics and thus improving the lighting rate, which is a technical effect.

In addition, according to the embodiment, in the side wiring technology that connects the panel wiring to the side of the light emitting device chip after self-assembly by DEP force in the internal technology, the short-circuit problem in which the side wiring is cut off at the lower edge of the light emitting device chip can be solved.

For example, the semiconductor light emitting device (150A) according to the embodiment may include a heat transferring insulating layer (157) disposed on the outside of the light emitting structure (152), and the technical effect is that the light emitting device (150A) significantly increases the lighting rate by preventing the short-circuit of the side wiring (290) and improving the electrical characteristics by the heat transferring insulating layer (157). For example, the embodiment has a special technical effect that can implement excellent contact characteristics (G) by forming a solid electrode film of the first side wiring (290a) and the second side wiring (290b) including a heat transferring insulating layer (157) disposed on the outside of the light emitting structure (152) of the semiconductor light emitting device (150A).

In addition, according to the embodiment, even if an electrical connection failure occurs in the bonding process of the semiconductor light emitting device (150A), a reliable electrical connection is made possible in the additional process, the hot press process, so that the lighting rate can be dramatically improved.

For example, according to the embodiment, by quickly transferring the heat by hot press to the lower edge portion of the semiconductor light emitting device (150A) by the heat transferring insulating layer (157) disposed on the outer periphery of the semiconductor light emitting device, the heat diffusion of the material of the side electrode is activated, thereby forming a solid electrode film of the first side wiring (290a) and the second side wiring (290b), thereby realizing a special technical effect of excellent contact characteristics (G).

For example, the side electrode may include a low-temperature metal material having a low melting point, such as Al, and the heat by hot press is quickly transferred to the lower edge portion of the semiconductor light emitting device by the heat transferring insulating layer (157), thereby activating the heat diffusion of the material of the side electrode, thereby forming a solid electrode film of the first side wiring (290a) and the second side wiring (290b), thereby realizing a special technical effect of excellent contact characteristics (G).

In addition, according to an embodiment, a heat transferring insulating layer (157) is disposed on the outer periphery of a semiconductor light emitting device (150A), and a passivation layer is disposed between the light emitting structure (152) and the heat transferring insulating layer (157). According to the embodiment, since heat or pressure in the hot press process is not directly transferred to the semiconductor light emitting device (150A), there is a technical effect that can prevent electrical and characteristic deterioration of the light emitting structure (152).

In addition, according to the embodiment, when heat is generated during display implementation in a display device having a semiconductor light emitting device (150A), it can be diffused to the outside through the heat transferring insulating layer (157), so there is a technical effect that can improve the reliability of the display device.

In addition, according to the embodiment, a heat transferring insulating layer (157) is disposed on the outer periphery of the semiconductor light emitting device (150A), and a part of the side electrode, for example, the first side wiring (290a), is extended and disposed not only on the light emitting structure (152) but also on the heat transferring insulating layer (157), thereby improving the bonding strength between the first side wiring (290a) and the heat transferring insulating layer (157), thereby improving the reliability of the device.

For example, there is a technical effect that the heat transferring insulating layer (157) can significantly improve the bonding force between the first side wiring (290a) and the heat transferring insulating layer (157) by including an oxide of a metal forming the side electrode, thereby improving the reliability of the device.

In addition, according to the embodiment, the internal technology can solve the problem that the semiconductor light emitting device assembled in the assembly hole is detached due to the weak fixing force between the semiconductor light emitting device and the dielectric layer on the assembly electrode.

For example, in the embodiment, the spare side wiring (290a) has a special technical effect that stably fixes the semiconductor light emitting device (150A).

The technical effects of the embodiment are not limited to those described in this item, and include those understood from the description of the invention.

### DESCRIPTION OF DRAWINGS

FIG. 1 is an example diagram of a living room of a house in which a display device according to the embodiment is placed.

FIG. 2 is a block diagram schematically showing a display device according to the embodiment.

FIG. 3 is a circuit diagram showing an example of a pixel of FIG. 2.

FIG. 4 is an enlarged view of a first panel area in the display device of FIG. 1.

FIG. 5 is a cross-sectional view along the line B1-B2 of the A2 area of FIG. 4.

FIG. 6 is an example diagram showing a light emitting device according to an embodiment being assembled on a substrate by a self-assembly method.

FIG. 7 is a partial enlarged view of the A3 area of FIG. 6.

FIG. 8 is a photograph showing a short circuit of a side wiring in an internal technology.

FIG. 9 is a cross-sectional view of a display device (300) having a semiconductor light emitting device according to an embodiment.

FIG. 10 is a detailed cross-sectional view of a display device (300) having a semiconductor light emitting device according to the embodiment illustrated in FIG. 9.

FIG. 11 is an example diagram of a photograph of a Cl area of a display device (300) having a semiconductor light emitting device according to the embodiment illustrated in FIG. 10.

FIGS. 12A to 12I are cross-sectional views of a manufacturing process of a display device (300) including a semiconductor light emitting device according to an embodiment.

FIG. 13 is a cross-sectional view of a display device (300B) including a semiconductor light emitting device according to a second embodiment.

### MODE FOR INVENTION

Hereinafter, the embodiments disclosed in the present specification will be described in detail with reference to the attached drawings. The suffixes ‘module’ and ‘part’ for components used in the following description are given or used interchangeably in consideration of the ease of writing the specification, and do not have distinct meanings or roles in themselves. In addition, the attached drawings are intended to facilitate easy understanding of the embodiments disclosed in the present specification, and the technical ideas disclosed in the present specification are not limited by the attached drawings. In addition, when an element such as a layer, region, or substrate is mentioned as existing ‘on’ another element, this includes that it may be directly on the other element or that other intermediate elements may exist between them.

The display device described in this specification may include a digital TV, a mobile phone, a smart phone, a laptop computer, a digital broadcasting terminal, a personal digital assistant (PDA), a portable multimedia player (PMP), a navigation, a slate PC, a tablet PC, an Ultra-Book, a desktop computer, etc. However, the configuration according to the embodiment described in this specification may also be applied to a device capable of displaying, even if it is a new product type developed in the future.

The following describes a light emitting device according to an embodiment and a display device including the same.

The following describes a semiconductor light emitting device according to an embodiment and a display device including the same.

FIG. 1 illustrates a living room of a house in which a display device (100) according to an embodiment is placed.

The display device (100) according to the embodiment can display the status of various electronic products such as a washing machine (101), a robot vacuum cleaner (102), and an air purifier (103), communicate with each electronic product based on IoT, and control each electronic product based on the user's setting data.

The display device (100) according to the embodiment can include a flexible display manufactured on a thin and flexible substrate. The flexible display can be bent or rolled like paper while maintaining the characteristics of a conventional flat panel display.

In the flexible display, visual information can be implemented by independently controlling the light emission of unit pixels disposed in a matrix form. A unit pixel means the minimum unit for implementing one color. The unit pixel of the flexible display can be implemented by a light emitting device. In the embodiment, the light emitting device can be a Micro-LED or a Nano-LED, but is not limited thereto.

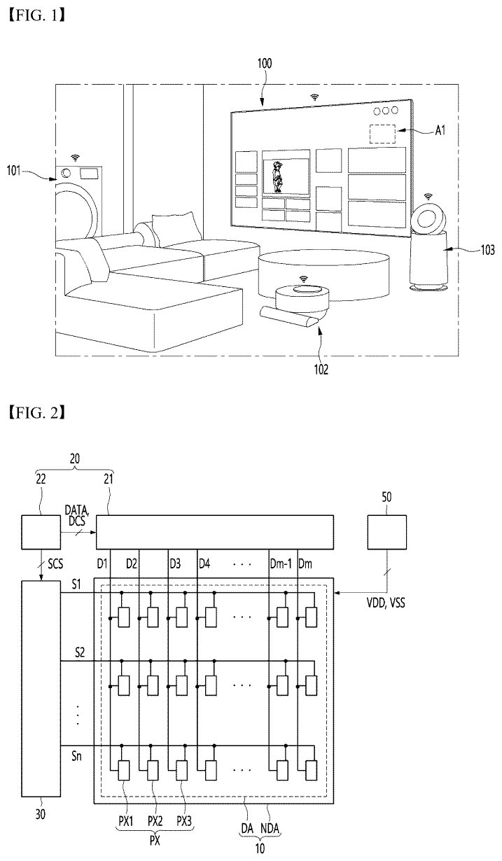

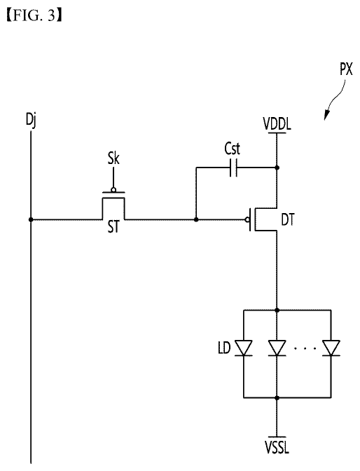

Next, FIG. 2 is a block diagram schematically showing a display device according to an embodiment, and FIG. 3 is a circuit diagram showing an example of pixels of FIG. 2.

Referring to FIG. 2 and FIG. 3, the display device according to the embodiment may include a display panel (10), a driving circuit (20), a scan driving unit (30), and a power supply circuit (50).

The display device (100) of the embodiment may drive a light emitting device in an active matrix (AM) method or a passive matrix (PM) method.

The driving circuit (20) may include a data driving unit (21) and a timing control unit (22).

The display panel (10) may be divided into a display area (DA) and a non-display area (NDA) disposed around the display area (DA). The display area (DA) is an area where pixels (PX) are formed to display an image. The display panel (10) may include data lines (D1 to Dm, m is an integer greater than or equal to 2), scan lines (S1 to Sn, n is an integer greater than or equal to 2) intersecting the data lines (D1 to Dm), a high-potential voltage line to which a high-potential voltage is supplied, a low-potential voltage line to which a low-potential voltage is supplied, and pixels (PX) connected to the data lines (D1 to Dm) and the scan lines (S1 to Sn).

Each of the pixels (PX) may include a first sub-pixel (PX1), a second sub-pixel (PX2), and a third sub-pixel (PX3). The first sub-pixel (PX1) may emit a first color light of a first wavelength, the second sub-pixel (PX2) may emit a second color light of a second wavelength, and the third sub-pixel (PX3) may emit a third color light of a third wavelength. The first color light may be red light, the second color light may be green light, and the third color light may be blue light, but the present invention is not limited thereto. In addition, although FIG. 2 exemplifies that each of the pixels (PX) includes three sub-pixels, the present invention is not limited thereto. That is, each of the pixels (PX) may include four or more sub-pixels.

Each of the first sub-pixel (PX1), the second sub-pixel (PX2), and the third sub-pixel (PX3) may be connected to at least one of the data lines (D1 to Dm), at least one of the scan lines (S1 to Sn), and a high-potential voltage line. The first sub-pixel (PX1) may include light emitting devices (LD), a plurality of transistors for supplying current to the light emitting devices (LD), and at least one capacitor (Cst), as shown in FIG. 3.

Although not shown in the drawing, each of the first sub-pixel (PX1), the second sub-pixel (PX2), and the third sub-pixel (PX3) may include only one light emitting device (LD) and at least one capacitor (Cst).

Each of the light emitting devices (LD) may be a semiconductor light emitting diode including a first electrode, a plurality of conductivity type semiconductor layers, and a second electrode. Here, the first electrode may be an anode electrode, and the second electrode may be a cathode electrode, but is not limited thereto.

Referring to FIG. 3, the plurality of transistors may include a driving transistor (DT) that supplies current to the light emitting devices (LD), and a scan transistor (ST) that supplies a data voltage to a gate electrode of the driving transistor (DT). The driving transistor (DT) may include a gate electrode connected to a source electrode of the scan transistor (ST), a source electrode connected to a high-potential voltage line to which a high-potential voltage is applied, and a drain electrode connected to the first electrodes of the light emitting devices (LD). The scan transistor (ST) may include a gate electrode connected to a scan line (Sk, where k is an integer satisfying 1≤k≤n), a source electrode connected to a gate electrode of a driving transistor (DT), and a drain electrode connected to a data line (Dj, where j is an integer satisfying 1≤j≤m).

A capacitor (Cst) is formed between the gate electrode and the source electrode of the driving transistor (DT). The storage capacitor (Cst) may charge a difference value between the gate voltage and the source voltage of the driving transistor (DT).

The driving transistor (DT) and the scan transistor (ST) may be formed as thin film transistors. In addition, in FIG. 3, the driving transistor (DT) and the scan transistor (ST) are formed as P-type MOSFET (Metal Oxide Semiconductor Field Effect Transistor), but the present invention is not limited thereto. The driving transistor (DT) and the scan transistor (ST) may also be formed as an N-type MOSFET. In this case, the positions of the source electrode and the drain electrode of each of the driving transistor (DT) and the scan transistor (ST) may be changed.

In addition, in FIG. 3, it is exemplified that each of the first sub-pixel (PX1), the second sub-pixel (PX2), and the third sub-pixel (PX3) includes a 2T1C (2 Transistor—1 capacitor) having one driving transistor (DT), one scan transistor (ST), and one capacitor (Cst), but the present invention is not limited thereto. Each of the first sub-pixel (PX1), the second sub-pixel (PX2), and the third sub-pixel (PX3) may include a plurality of scan transistors (ST) and a plurality of capacitors (Cst).

Referring again to FIG. 2, the driving circuit (20) outputs signals and voltages for driving the display panel (10). For this purpose, the driving circuit (20) may include a data driving unit (21) and a timing control unit (22).

The data driving unit (21) receives digital video data (DATA) and a source control signal (DCS) from the timing control unit (22). The data driving unit (21) converts digital video data (DATA) into analog data voltages according to the source control signal (DCS) and supplies them to the data lines (D1 to Dm) of the display panel (10).

The timing control unit (22) receives digital video data (DATA) and timing signals from the host system. The timing signals may include a vertical sync signal, a horizontal sync signal, a data enable signal, and a dot clock. The host system may be an application processor of a smartphone or tablet PC, a monitor, a system on chip of a TV, etc.

The scan driving unit (30) receives a scan control signal (SCS) from the timing control unit (22). The scan driving unit (30) generates scan signals according to the scan control signal (SCS) and supplies them to the scan lines (S1 to Sn) of the display panel (10). The scan driving unit (30) may include a plurality of transistors and may be formed in a non-display area (NDA) of the display panel (10). Alternatively, the scan driving unit (30) may be formed as an integrated circuit, in which case it may be mounted on a gate flexible film attached to the other side of the display panel (10).

The power supply circuit (50) can generate a high-potential voltage (VDD) and a low-potential voltage (VSS) for driving the light emitting devices (LD) of the display panel (10) from the main power supply and supply them to the high-potential voltage line and the low-potential voltage line of the display panel (10). In addition, the power supply circuit (50) can generate and supply driving voltages for driving the driving circuit (20) and the scan driving unit (30) from the main power supply.

Next, FIG. 4 is an enlarged view of the first panel area (A1) in the display device of FIG. 1.

According to FIG. 4, the display device (100) of the embodiment can be manufactured by mechanically and electrically connecting a plurality of panel areas such as the first panel area (A1) by tiling.

The first panel area (A1) can include a plurality of light emitting devices (150) disposed for each unit pixel (PX of FIG. 2).

For example, a unit pixel (PX) may include a first sub-pixel (PX1), a second sub-pixel (PX2), and a third sub-pixel (PX3). For example, a plurality of red light emitting devices (150R) may be disposed in a first sub-pixel (PX1), a plurality of green light emitting devices (150G) may be disposed in a second sub-pixel (PX2), and a plurality of blue light emitting devices (150B) may be disposed in a third sub-pixel (PX3). The unit pixel (PX) may further include a fourth sub-pixel in which no light emitting devices are disposed, but this is not limited thereto. Meanwhile, the light emitting device (150) may be a semiconductor light emitting device.

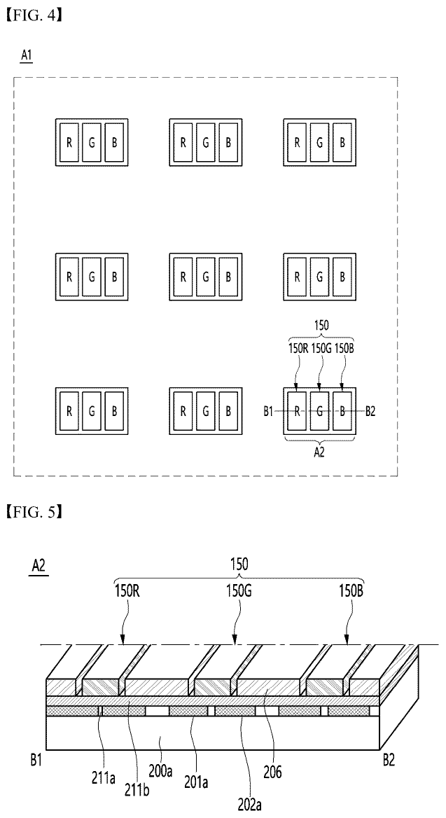

Next, FIG. 5 is a cross-sectional view along the line B1-B2 of the A2 region of FIG. 4.

Referring to FIG. 5, the display device (100) of the embodiment may include a substrate (200a), spaced wiring (201a, 202a), a first insulating layer (211a), a second insulating layer (211b), a third insulating layer (206), and a plurality of light emitting devices (150).

The wiring may include a first wiring (201a) and a second wiring (202a) spaced from each other. The first wiring (201a) and the second wiring (202a) may function as panel wiring for applying power to the light emitting devices (150) in the panel, and may also function as assembly electrodes for generating a dielectric force for assembly in the case of self-assembly of the light emitting devices (150).

The wiring (201a, 202a) may be formed of a transparent electrode (ITO) or may include a metal material having excellent electrical conductivity. For example, the wiring (201a, 202a) may be formed of at least one of titanium (Ti), chromium (Cr), nickel (Ni), aluminum (Al), platinum (Pt), gold (Au), tungsten (W), and molybdenum (Mo), or an alloy thereof.

A first insulating layer (211a) may be disposed between the first wiring (201a) and the second wiring (202a), and a second insulating layer (211b) may be disposed on the first wiring (201a) and the second wiring (202a). The first insulating layer (211a) and the second insulating layer (211b) may be an oxide film, a nitride film, or the like, but are not limited thereto.

The light emitting device (150) may include a red light emitting device (150R), a green light emitting device (150G), and a blue light emitting device (150B0) to form a unit pixel (sub-pixel), but is not limited thereto, and may include a red fluorescent substance and a green fluorescent substance to implement red and green, respectively.

The substrate (200a) may be formed of glass or polyimide. In addition, the substrate (200a) may include a flexible material such as PEN (Polyethylene Naphthalate) or PET (Polyethylene Terephthalate). In addition, the substrate (200) may be a transparent material, but is not limited thereto. The substrate (200a) may function as a support substrate in the panel, and may also function as an assembly substrate when self-assembling the light emitting device.

The third insulating layer (206) may include an insulating and flexible material such as polyimide, PEN, PET, etc. It can be formed integrally with the substrate (200a) to form a single substrate.

The third insulating layer (206) can be a conductive adhesive layer having adhesiveness and conductivity, and the conductive adhesive layer can be flexible to enable a flexible function of the display device. For example, the third insulating layer (206) can be a conductive adhesive layer such as an anisotropic conductive film (ACF) or an anisotropic conductive medium, a solution containing conductive particles, etc. The conductive adhesive layer can be a layer that is electrically conductive in the vertical direction with respect to the thickness, but electrically insulating in the horizontal direction with respect to the thickness.

The gap between the first and second wirings (201a, 202a) is formed smaller than the width of the light emitting device (150) and the width of the assembly hole (203H), so that the assembly position of the light emitting device (150) using the electric field can be more precisely fixed.

A third insulating layer (206) is formed on the first and second wirings (201a, 202a) to protect the first and second wirings (201a, 202a) from the fluid (1200) and prevent leakage of current flowing through the first and second wirings (201a, 202a). The third insulating layer (206) may be formed as a single layer or multiple layers of an inorganic insulator such as silica or alumina or an organic insulator.

In addition, the third insulating layer (206) may include an insulating and flexible material such as polyimide, PEN, PET, etc., and may be formed integrally with the substrate (200) to form a single substrate.

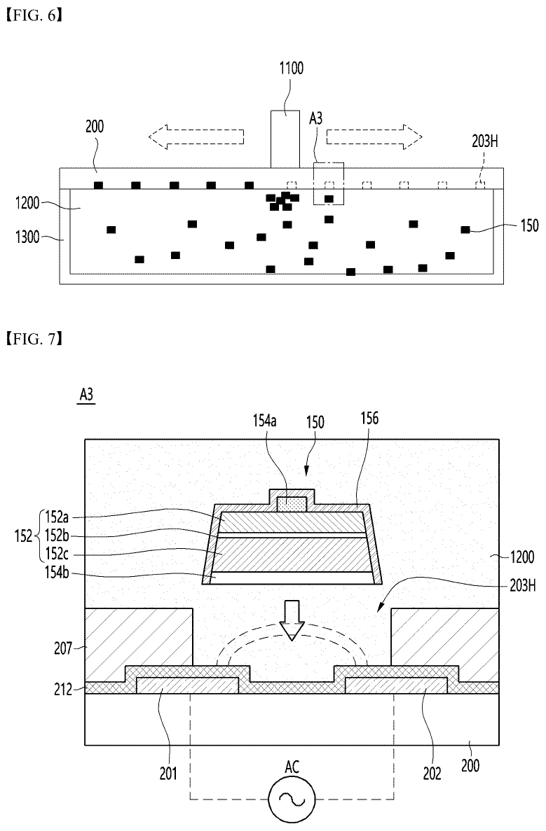

The third insulating layer (206) may have a partition wall, and an assembly hole (203H) may be formed by the partition wall. For example, the third insulating layer (206) may include an assembly hole (203H) for inserting the light emitting device (150) (see FIG. 6). Therefore, during self-assembly, the light emitting device (150) can be easily inserted into the assembly hole (203H) of the third insulating layer (206). The assembly hole (203H) may be called an insertion hole, a fixing hole, an alignment hole, etc.

The assembly hole (203H) may have a shape and size corresponding to the shape of the light emitting device (150) to be assembled at the corresponding position. Accordingly, it is possible to prevent another light emitting device from being assembled into the assembly hole (203H) or multiple light emitting devices from being assembled.

Next, FIG. 6 is a drawing showing an example of a light emitting device according to an embodiment being assembled to a substrate by a self-assembly method, and FIG. 7 is a partial enlarged view of area A3 of FIG. 6. FIG. 7 is a drawing in which area A3 is rotated 180 degrees for convenience of explanation.

Based on FIGS. 6 and 7, an example of assembling a semiconductor light emitting device according to an embodiment into a display panel by a self-assembly method using an electromagnetic field will be described.

The assembly substrate (200) described below can also function as a panel substrate (200a) in a display device after assembling the light emitting device, but the embodiment is not limited thereto.

Referring to FIG. 6, a semiconductor light emitting device (150) can be introduced into a chamber (1300) filled with a fluid (1200), and the semiconductor light emitting device (150) can be moved to the assembly substrate (200) by a magnetic field generated from an assembly device (1100). At this time, a light emitting device (150) adjacent to an assembly hole (203H) of an assembly substrate (200) can be assembled into an assembly hole (230) by a dielectrophoretic force caused by an electric field of assembly electrodes. The fluid (1200) may be, but is not limited to, ultrapure water. The chamber may be called a tank, a container, a vessel, etc.

After the semiconductor light emitting device (150) is introduced into the chamber (1300), the assembly substrate (200) may be placed on the chamber (1300). Depending on the embodiment, the assembly substrate (200) may be introduced into the chamber (1300).

Referring to FIG. 7, the semiconductor light emitting device (150) may be implemented as a vertical semiconductor light emitting device as illustrated, but is not limited thereto, and a horizontal light emitting device may be employed.

The semiconductor light emitting device (150) may include a magnetic layer (not illustrated) having a magnetic body. The magnetic layer may include a metal having magnetism, such as nickel (Ni). The semiconductor light emitting device (150) injected into the fluid includes a magnetic layer, and thus can move to the assembly substrate (200) by a magnetic field generated from the assembly device (1100). The magnetic layer can be disposed on the upper side or lower side or both sides of the light emitting device.

The semiconductor light emitting device (150) can include a passivation layer (156) surrounding the upper surface and the side surface. The passivation layer (156) can be formed by an inorganic insulator such as silica or alumina through PECVD, LPCVD, sputtering deposition, etc. In addition, the passivation layer (156) can be formed by a method of spin coating an organic material such as a photoresist or a polymer material.

The semiconductor light emitting device (150) can include a first conductivity type semiconductor layer (152a), a second conductivity type semiconductor layer (152c), and an active layer (152b) disposed therebetween. The first conductivity type semiconductor layer (152a) may be an n-type semiconductor layer, and the second conductivity type semiconductor layer (152c) may be a p-type semiconductor layer, but is not limited thereto.

A first electrode layer (154a) may be disposed on the first conductivity type semiconductor layer (152a), and a second electrode layer (154b) may be disposed on the second conductivity type semiconductor layer (152c). To this end, a portion of the first conductivity type semiconductor layer (152a) or the second conductivity type semiconductor layer (152c) may be exposed to the outside. Accordingly, after the semiconductor light emitting device (150) is assembled on the assembly substrate (200), a portion of the passivation layer (156) may be etched in the manufacturing process of the display device.

The assembly substrate (200) may include a pair of first assembly electrodes (201) and second assembly electrodes (202) corresponding to each of the semiconductor light emitting devices (150) to be assembled. The first assembly electrodes (201) and the second assembly electrodes (202) may be formed by laminating multiple single metals or metal alloys, metal oxides, etc. For example, the first assembly electrodes (201) and the second assembly electrodes (202) may be formed by including at least one of Cu, Ag, Ni, Cr, Ti, Al, Rh, Pd, Ir, Ru, Mg, Zn, Pt, Au, and Hf, but are not limited thereto.

In addition, the first assembly electrode (201) and the second assembly electrode (202) may be formed by including at least one of ITO (indium tin oxide), IZO (indium zinc oxide), IZTO (indium zinc tin oxide), IAZO (indium aluminum zinc oxide), IGZO (indium gallium zinc oxide), IGTO (indium gallium tin oxide), AZO (aluminum zinc oxide), ATO (antimony tin oxide), GZO (gallium zinc oxide), IZON (IZO Nitride), AGZO (Al—Ga ZnO), IGZO (In—Ga ZnO), ZnO, IrOx, RuOx, NiO, RuOx/ITO, Ni/IrOx/Au, and Ni/IrOx/Au/ITO, but are not limited thereto.

The first assembly electrode (201) and the second assembly electrode (202) can fix the semiconductor light emitting device (150) inserted into the assembly hole (203H) by the dielectric force by emitting an electric field when an AC voltage is applied. The gap between the first assembly electrode (201) and the second assembly electrode (202) can be smaller than the width of the semiconductor light emitting device (150) and the width of the assembly hole (203H), and the assembly position of the semiconductor light emitting device (150) can be fixed more precisely using the electric field.

A first insulating layer (212) is formed on the first assembly electrode (201) and the second assembly electrode (202), thereby protecting the first assembly electrode (201) and the second assembly electrode (202) from the fluid (1200) and preventing leakage of current flowing through the first assembly electrode (201) and the second assembly electrode (202). For example, the first insulating layer (212) may be formed of a single layer or multiple layers of an inorganic insulator such as silica or alumina, or an organic insulator. The first insulating layer (212) may have a minimum thickness to prevent damage to the first assembly electrode (201) and the second assembly electrode (202) when assembling the semiconductor light emitting device (150), and may have a maximum thickness to stably assemble the semiconductor light emitting device (150).

A partition wall (207) may be formed on the upper portion of the first insulating layer (212). A portion of the partition wall (207) may be positioned on the upper portion of the first assembly electrode (201) and the second assembly electrode (202), and the remaining portion may be positioned on the upper portion of the assembly substrate (200).

Meanwhile, when manufacturing the assembly substrate (200), some of the partition walls formed over the entire upper portion of the first insulating layer (212) are removed, so that an assembly hole (203H) in which each of the semiconductor light emitting devices (150) is coupled and assembled to the assembly substrate (200) can be formed.

An assembly hole (203H) in which the semiconductor light emitting devices (150) are coupled is formed in the assembly substrate (200), and a surface on which the assembly hole (203H) is formed can come into contact with a fluid (1200). The assembly hole (203H) can guide the exact assembly position of the semiconductor light emitting device (150).

Meanwhile, the assembly hole (203H) can have a shape and size corresponding to the shape of the semiconductor light emitting device (150) to be assembled at the corresponding position. Accordingly, it is possible to prevent another semiconductor light emitting device from being assembled in the assembly hole (203H) or a plurality of semiconductor light emitting devices from being assembled.

Referring back to 6, after the assembly substrate (200) is placed in the chamber, the assembly device (1100) that applies a magnetic field can move along the assembly substrate (200). The assembly device (1100) can be a permanent magnet or an electromagnet.

The assembly device (1100) can move in contact with the assembly substrate (200) to maximize the area affected by the magnetic field into the fluid (1200). Depending on the embodiment, the assembly device (1100) can include a plurality of magnetic bodies or can include magnetic bodies of a size corresponding to the assembly substrate (200). In this case, the movement distance of the assembly device (1100) can be limited to a predetermined range.

The semiconductor light emitting device (150) in the chamber (1300) can move toward the assembly device (1100) and the assembly substrate (200) by the magnetic field generated by the assembly device (1100).

Referring to FIG. 7, the semiconductor light emitting device (150) may be fixed by entering the assembly hole (203H) by the dielectrophoretic force (DEP force) formed by the electric field of the assembly electrode of the assembly board while moving toward the assembly device (1100).

Specifically, the first and second assembly wirings (201, 202) form an electric field by the AC power, and the dielectrophoretic force may be formed between the assembly wirings (201, 202) by this electric field. The semiconductor light emitting device (150) may be fixed to the assembly hole (203H) on the assembly substrate (200) by this dielectrophoretic force.

At this time, a predetermined solder layer (not shown) may be formed between the light emitting device (150) assembled on the assembly hole (203H) of the assembly substrate (200) and the assembly electrode to improve the bonding strength of the light emitting device (150).

In addition, a molding layer (not shown) may be formed in the assembly hole (203H) of the assembly substrate (200) after assembly. The molding layer may be a transparent resin or a resin containing a reflective material or a scattering material.

Since the time required for each semiconductor light emitting device to be assembled on the board can be drastically shortened by the self-assembly method using the electromagnetic field described above, a large-area high-pixel display can be implemented more quickly and economically.

According to the non-public internal technology, DEP Force is required for self-assembly, but there is a problem that the semiconductor light emitting device is not in the correct position in the assembly hole when assembling using self-assembly due to the difficulty in uniform control of the DEP Force.

In addition, due to this phenomenon of the semiconductor light emitting device being swayed, the electrical contact characteristics deteriorate in the subsequent electrical contact process, resulting in poor lighting rate and reduced yield.

Therefore, according to the non-public internal technology, DEP Force is required for self-assembly, but when using DEP Force, it faces a technical contradiction in that the electrical contact characteristics deteriorate due to the tendency of the semiconductor light emitting device to drift.

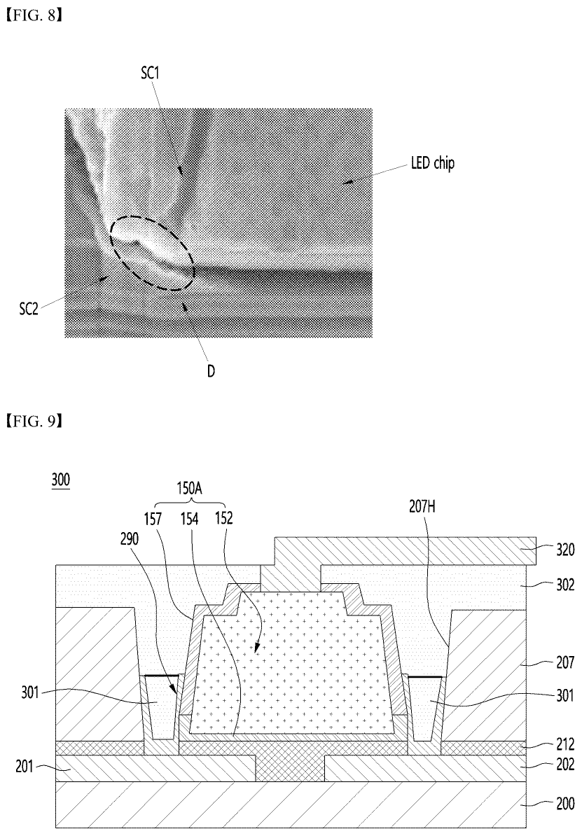

FIG. 8 is a photograph showing a short circuit in the side wiring in the internal technology.

In order to solve the problem of the tendency of the semiconductor light emitting device to drift after self-assembly by DEP Force, the internal technology is studying the side contact wire technology that connects the panel wiring to the side of the light emitting device chip (LED chip).

However, as shown in FIG. 8, there is a problem in that a short circuit (D) occurs at the bottom edge of the light emitting device chip in the side wiring process of the internal technology.

Specifically, the first side contact wiring (SC1) formed on the side of the light emitting device chip (LED chip) and the second side contact wiring (SC2) formed on the lower side of the light emitting device chip (LED chip) are having a short circuit (D) problem at the lower edge of the light emitting device chip (LED chip), which is causing a lighting failure.

In order to solve this short circuit problem at the edge in the internal technology, the side contact wiring is deposited in multiple to increase the thickness of the side contact wiring by forming it, but it was difficult to solve the short-circuit problem at the chip edge.

In addition, research was conducted to remove the assembly barrier using O₂ plasma before the deposition of the side contact wiring to solve the short-circuit problem at the edge in the internal technology, but it took about 40 minutes or more to remove the assembly barrier, and a reliability problem was discovered due to damage to the wiring of the assembled LED chip.

Meanwhile, in the internal technology, a process of draining the fluid in the tank is performed after assembly using DEP force, but when the power to the assembly electrode is cut off and there is no DEP force, the fixing force between the semiconductor light emitting device and the dielectric layer on the assembly electrode is weak, so the fluid draining process takes tens of minutes or more, and a problem occurs in which the semiconductor light emitting device assembled in the assembly hole is detached.

In addition, in the internal technology, when the electrode process of the panel unit is performed after assembly using the DEP force, the power to the assembly electrode is cut off, and if there is no DEP force, the fixing force between the semiconductor light emitting device and the dielectric layer on the assembly electrode is weak, causing a problem in which the semiconductor light emitting device assembled in the assembly hole is detached.

To solve this problem, the internal technology conducted research to fix the LED chip by filling the space between the lower part of the LED chip and the lower assembly electrode with a chip-fixing organic film such as PR using capillary phenomena. However, there is a problem of poor coating in the organic film coating process, and the chip detachment problem was not completely solved.

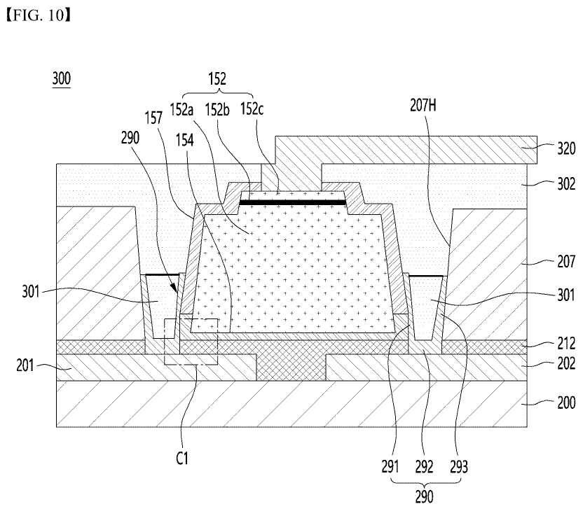

FIG. 9 is a cross-sectional view of a display device (300) equipped with a semiconductor light emitting device according to an embodiment, and FIG. 10 is a detailed cross-sectional view of a display device (300) equipped with a semiconductor light emitting device according to the embodiment illustrated in FIG. 9.

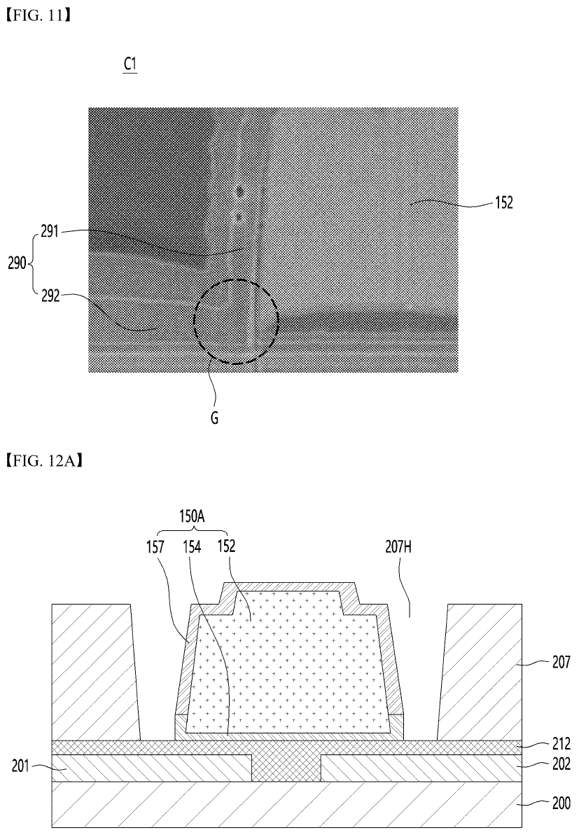

FIG. 11 is a photographic example of the C1 region of a display device (300) equipped with a semiconductor light emitting device according to the embodiment illustrated in FIG. 10.

Referring to FIGS. 9 and 10, a display device (300) having a semiconductor light emitting device according to an embodiment may include a substrate (200), a first assembly electrode (201), a second assembly electrode (202) that are spaced apart from each other on the substrate (200), a first insulating layer (212) that is disposed on the first assembly electrode (201) and the second assembly electrode (202), an assembly partition (207) that includes a predetermined assembly hole (207H) and is disposed on the first insulating layer (212), a semiconductor light emitting device (150A) that is disposed in the assembly hole (207H), a side wiring (290) that is electrically connected to a side of the semiconductor light emitting device (150A), and a second panel electrode (320) that is electrically connected to an upper side of the semiconductor light emitting device (150A).

The semiconductor light emitting device (150A) may include a light emitting structure (152), a lower electrode layer (154) disposed on the lower side of the light emitting structure (152), and a heat transferring insulating layer (157) disposed on the outer side of the light emitting structure (152). The semiconductor light emitting device (150A) may further include a passivation layer (not shown) between the light emitting structure (152) and the heat transferring insulating layer (157).

Referring to FIG. 10, the light emitting structure (152) may include a first conductivity type semiconductor layer (152a), a second conductivity type semiconductor layer (152c), and an active layer (152b) disposed therebetween. The first conductivity type semiconductor layer (152a) may be an n-type semiconductor layer, and the second conductivity type semiconductor layer (152c) may be a p-type semiconductor layer, but is not limited thereto.

The side wiring (290) may be electrically connected to the first conductivity type semiconductor layer (152a) of the semiconductor light emitting device (150A). For example, the side wiring (290) may be electrically connected to the first conductivity type semiconductor layer (152a) of the semiconductor light emitting device (150A) through the lower electrode layer (154), but is not limited thereto.

The side wiring (290) may include a first side wiring (290a) disposed on the side of the semiconductor light emitting device (150A), a second side wiring (290b) electrically contacting at least one of the first and second assembly electrodes (201, 202), and a third side wiring (290c) in contact with the assembly partition (207).

The embodiment may include a first planarization layer (301) and a second planarization layer (302) disposed within the assembly hole (207H). The first planarization layer (301) and the second planarization layer (302) may be formed of an insulating material.

The first planarization layer (301) may be disposed within the side wiring (290).

The embodiment may include a second planarization layer (302) disposed on the first planarization layer (301) and the side wiring (290). The second planarization layer (302) may be disposed between the side wiring (290) and the active layer (152b) of the semiconductor light emitting device (150A) to prevent electrical short-circuiting and improve reliability.

Next, FIG. 11 is a photographic example of the C1 region of a display device (300) having a semiconductor light emitting device according to the embodiment illustrated in FIG. 10.

In the embodiment, the semiconductor light emitting device (150A) may include a heat transferring insulating layer (157) disposed outside the light emitting structure (152), and the heat transferring insulating layer (157) prevents short-circuiting of the side wiring (290) and improves electrical characteristics, thereby significantly increasing the lighting rate, which has a technical effect.

For example, the embodiment has a special technical effect of implementing excellent contact characteristics (G) by forming a solid electrode film of the first side wiring (290a) and the second side wiring (290b) by including a heat transferring insulating layer (157) disposed outside the light emitting structure (152) of the semiconductor light emitting device (150A).

According to the embodiment, even if an electrical connection failure occurs in the bonding process of the semiconductor light emitting device (150A), a reliable electrical connection is made possible in the additional hot press process, thereby dramatically improving the lighting rate.

For example, according to the embodiment, by quickly transferring the heat due to the hot press to the lower edge of the semiconductor light emitting device by the heat transferring insulating layer (157) disposed on the outer periphery of the semiconductor light emitting device (150A), the heat diffusion of the material of the side electrode is activated, thereby forming a solid electrode film of the first side wiring (290a) and the second side wiring (290b), thereby realizing excellent contact characteristics (G), there is a special technical effect.

For example, the side electrode may include a low-temperature metal material having a low melting point, such as Al, and the heat caused by the hot press is quickly transferred to the lower edge of the semiconductor light emitting device by the heat transferring insulating layer (157), thereby activating the heat diffusion of the material of the side electrode, thereby forming a solid electrode film of the first side wiring (290a) and the second side wiring (290b), thereby realizing excellent contact characteristics (G).

In addition, according to the embodiment, since the heat transferring insulating layer (157) is disposed on the outer periphery of the semiconductor light emitting device (150A) and the passivation layer is disposed between the light emitting structure (152) and the heat transferring insulating layer (157), the heat or pressure in the hot press process is not directly transferred to the semiconductor light emitting device (150A), thereby preventing electrical and characteristic degradation of the light emitting structure (152).

In addition, according to the embodiment, when heat is generated during display implementation in a display device having a semiconductor light emitting device (150A), the heat can be diffused to the outside through the heat transferring insulating layer (157), so that there is a technical effect of improving the reliability of the display device.

In addition, according to the embodiment, the heat transferring insulating layer (157) is disposed on the outer periphery of the semiconductor light emitting device (150A), and a part of the side electrode, for example, the first side wiring (290a), is extended and disposed not only on the light emitting structure (152) but also on the heat transferring insulating layer (157), thereby improving the bonding strength between the first side wiring (290a) and the heat transferring insulating layer (157), so that the reliability of the element can be improved.

For example, there is a technical effect that can significantly improve the reliability of the device by significantly improving the bonding strength between the first side wiring (290a) and the heat transferring insulating layer (157) by including an oxide of the metal that constitutes the side electrode in the heat transferring insulating layer (157).

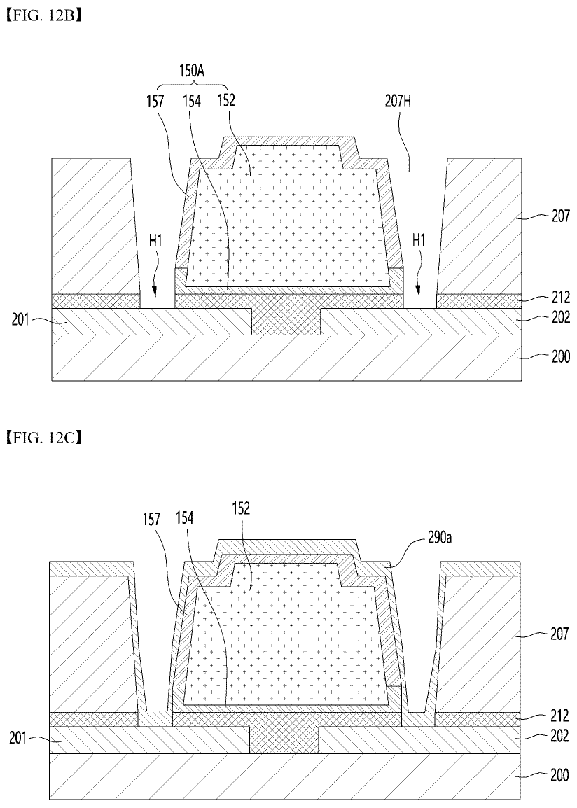

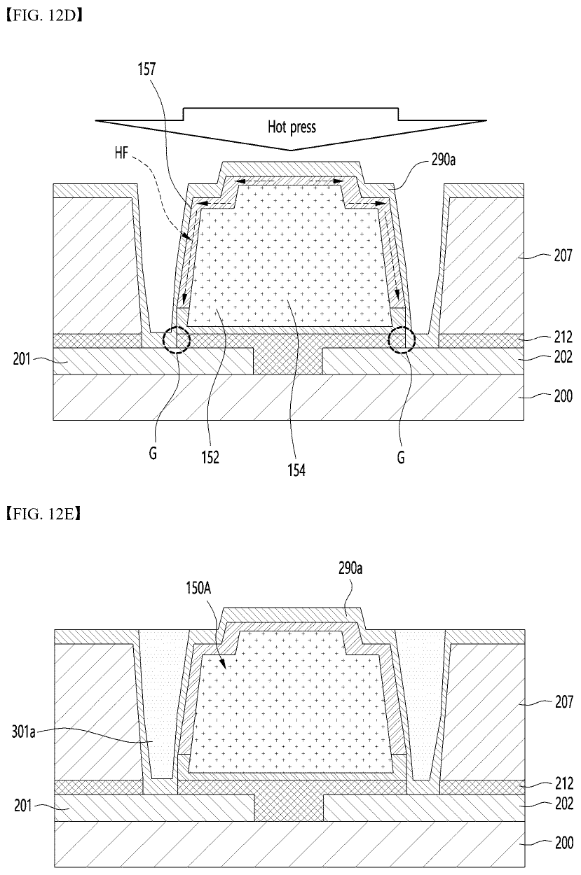

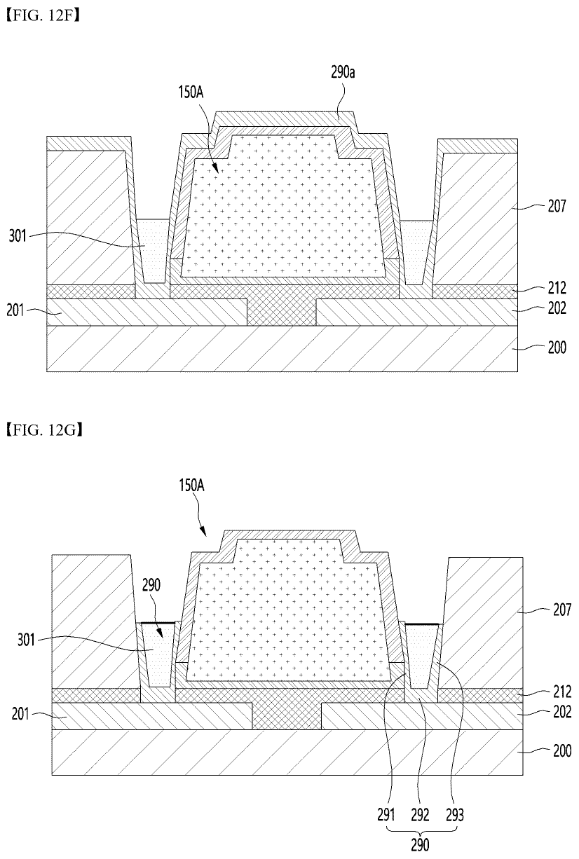

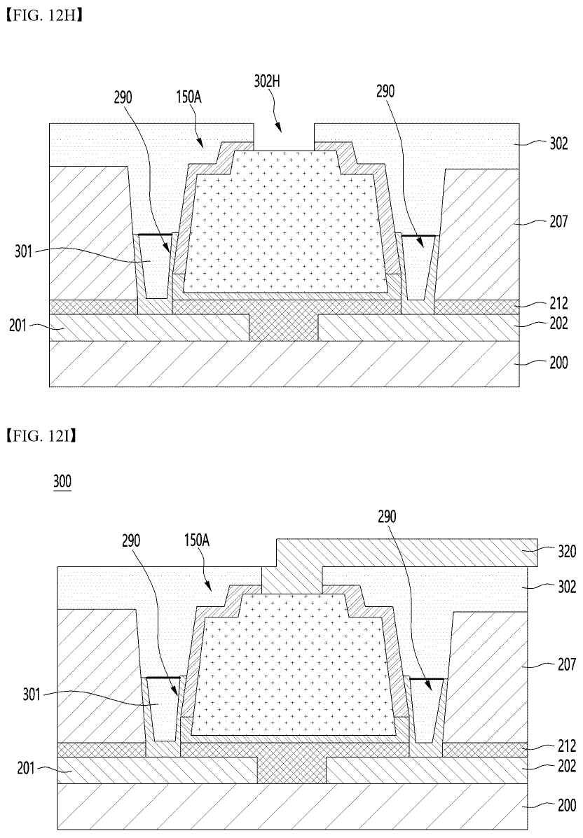

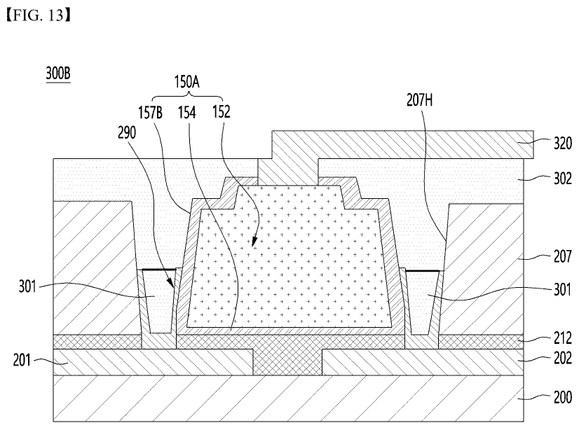

Next, FIGS. 12A to 12I are cross-sectional views of a manufacturing process of a display device (300) including a semiconductor light emitting device according to an embodiment.

Referring to FIG. 12A, a display device (300) having a semiconductor light emitting device according to an embodiment may include a first assembly electrode (201), a second assembly electrode (202) spaced apart from each other on an assembly substrate (200), a first insulating layer (212) disposed between the first assembly electrode (201) and the second assembly electrode (202), an assembly partition (207) including a predetermined assembly hole (207H) and disposed on the first insulating layer (212), and a conductor light emitting device (150A) disposed within the assembly hole (207H).

The semiconductor light emitting device (150A) may be assembled using a DEP force using the first assembly electrode (201) and the second assembly electrode (202).

The semiconductor light emitting device (150A) may include a light emitting structure (152), a lower electrode layer (154) disposed on the lower side of the light emitting structure (152), and a heat transferring insulating layer (157) disposed on the outer side of the light emitting structure (152). The semiconductor light emitting device (150A) may further include a passivation layer (not shown) between the light emitting structure (152) and the heat transferring insulating layer (157).

Next, referring to FIG. 12B, a portion of the first insulating layer (212) in the assembly hole (207H) may be removed to form an insulating layer penetration hole (H1) through which the upper side of the first assembly electrode (201) and the second assembly electrode (202) is exposed.

Next, referring to FIG. 12C, a preliminary side wiring layer (290a) is formed on the exposed semiconductor light emitting device (150A), the assembly partition (207), and the exposed first assembly electrode (201), the second assembly electrode.

The preliminary side wiring (290a) may be a metal layer or a conductive photosensitive material. For example, the preliminary side wiring (290a) may be Al or an Al alloy, but is not limited thereto. In addition, the preliminary side wiring (290a) may be Mo/Al/Mo or AuGe, but is not limited thereto.

In addition, the preliminary side wiring (290a) may be a conductive photosensitive material. For example, the preliminary side wiring (290a) may include a conductive liquid photosensitive material. For example, the preliminary side wiring (290a) may be formed by performing an exposure and development process after forming a conductive liquid photosensitive material. The preliminary side wiring (290a) may be a mixture of a conductive polymer and a photosensitive polymer, but is not limited thereto.

In the embodiment, the preliminary side wiring (290a) has a special technical effect of stably fixing the semiconductor light emitting device (150A).

Accordingly, according to the embodiment, the problem of the semiconductor light emitting device being detached from the assembly hole due to the weak fixing force between the semiconductor light emitting device and the dielectric layer on the assembly electrode in the internal technology can be solved.

Next, referring to FIG. 12D, a predetermined hot press process can be performed. diffusion bonding of a metal material, for example, an Al material, in the preliminary side wiring (290a) can be performed by the hot press process. The hot press process can be in the range of 0.3 to 0.8 of the melting point, and the pressure can be 0.04 to 0.1 Mpa. For example, the temperature of the hot press process can be in the range of about 200 to 250 °C, but is not limited thereto.

According to the embodiment, even if an electrical connection failure occurs in the bonding process of the semiconductor light emitting device (150A), a reliable electrical connection can be possible in the additional hot press process, thereby drastically improving the lighting rate.

For example, according to the embodiment, by forming a heat flow (HF) that quickly transfers heat by hot press to the lower edge of the semiconductor light emitting device by the heat transferring insulating layer (157) disposed on the outer periphery of the semiconductor light emitting device (150A), the activation of heat diffusion of the material of the side electrode or electromigration between the interfaces can be induced.

Through this, a solid electrode film of the first side wiring (290a) and the second side wiring (290b) can be formed, thereby providing a special technical effect of implementing excellent contact characteristics (G).

For example, the side electrode may include a low-temperature metal material having a low melting point, such as Al, and the heat caused by the hot press is quickly transferred to the lower edge of the semiconductor light emitting device by the heat transferring insulating layer (157), thereby activating the heat diffusion of the material of the side electrode, thereby forming a solid electrode film of the first side wiring (290a) and the second side wiring (290b), thereby implementing excellent contact characteristics (G), which has a special technical effect.

In the embodiment, the semiconductor light emitting device (150A) may include a heat transferring insulating layer (157) disposed on the outside of the light emitting structure (152), and the heat transferring insulating layer (157) prevents the short-circuiting of the side wiring (290) and improves the electrical characteristics, thereby significantly increasing the lighting rate.

For example, the embodiment has a special technical effect of forming a solid electrode film of the first side wiring (290a) and the second side wiring (290b) by including a heat transferring insulating layer (157) disposed on the outer periphery of the light emitting structure (152) of the semiconductor light emitting device (150A), thereby realizing excellent contact characteristics.

In addition, according to the embodiment, since the heat transferring insulating layer (157) is disposed on the outer periphery of the semiconductor light emitting device (150A), heat or pressure in the hot press process is not directly transferred to the semiconductor light emitting device (150A), thereby preventing electrical and characteristic degradation of the light emitting structure (152).

In addition, according to the embodiment, when heat is generated during display implementation in a display device equipped with a semiconductor light emitting device (150A), it can be diffused to the outside through the heat transferring insulating layer (157), thereby improving the reliability of the display device.

In addition, according to the embodiment, a heat transferring insulating layer (157) is disposed on the outer periphery of a semiconductor light emitting device (150A), and a part of a side electrode, for example, a first side wiring (290a), is extended and disposed not only on the light emitting structure (152) but also on the heat transferring insulating layer (157) (see FIG. 12G), thereby improving the bonding strength between the first side wiring (290a) and the heat transferring insulating layer (157), thereby improving the reliability of the element.

For example, there is a technical effect in which the heat transferring insulating layer (157) includes an oxide of a metal forming the side electrode, thereby significantly improving the bonding strength between the first side wiring (290a) and the heat transferring insulating layer (157), thereby improving the reliability of the element.

Next, referring to FIG. 12E, a first preliminary planarization layer (301a) is formed on the preliminary side wiring (290a).

The first preliminary planarization layer (301a) may be a PAC (photoactive compound) and may be formed of photoacryl, but is not limited thereto. In addition, the first preliminary planarization layer (301a) may be a compound that imparts photosensitivity to a binder resin, such as an acrylic photosensitive resin, a novolak resin system, a polyimide or siloxane system, but is not limited thereto.

Next, referring to FIG. 12F, a portion of the upper side of the first preliminary planarization layer (301a) is removed to expose the upper surface and the side surface of the preliminary side wiring (290a).

For example, the first planarization layer (301) may be formed by removing a portion of the upper side of the first preliminary planarization layer (301a) by dry etching, etc. so that the first conductivity type semiconductor layer (152a) of the semiconductor light emitting device (150A) is exposed.

Next, referring to FIG. 12G, the exposed spare side wiring (290a) can be removed to form the side wiring (290).

The side wiring (290) can include a first side wiring (290a) disposed on the side of the semiconductor light emitting device (150A), a second side wiring (290b) electrically contacting at least one of the first and second assembly electrodes (201, 202), and a third side wiring (290c) in contact with the assembly partition (207).

Next, referring to FIG. 12H, a second planarization layer (302) can be formed on the semiconductor light emitting device (150A) and the assembly partition (207). The second flattening layer (302) may also be disposed between the side wiring (290) and the active layer (152b) of the semiconductor light emitting device (150A) to prevent electrical short-circuiting and improve reliability.

Afterwards, a third through hole (302H) may be formed by removing a portion of the second flattening layer (302) to open a portion of the upper surface of the semiconductor light emitting device (150A).

Referring to FIG. 12I, a second panel electrode (320) electrically connected to the upper surface of the semiconductor light emitting device (150A) may be formed.

Next, FIG. 13 is a cross-sectional view of a display device (300B) including a semiconductor light emitting device according to the second embodiment.

The second embodiment may adopt the technical features of the previously described embodiment.

For example, a display device (300B) having a semiconductor light emitting device according to the second embodiment may include a substrate (200), a first assembly electrode (201), a second assembly electrode (202) that are disposed spaced apart from each other on the substrate (200), a first insulating layer (212) that is disposed on the first assembly electrode (201) and the second assembly electrode (202), an assembly partition (207) that includes a predetermined assembly hole (207H) and is disposed on the first insulating layer (212), a semiconductor light emitting device (150A) that is disposed in the assembly hole (207H), a side wiring (290) that is electrically connected to a side of the semiconductor light emitting device (150A), and a second panel electrode (320) that is electrically connected to an upper side of the semiconductor light emitting device (150A).

The semiconductor light emitting device (150A) may include a light emitting structure (152), a lower electrode layer (154) disposed on the lower side of the light emitting structure (152), and a second heat transferring insulating layer (157B) disposed on the outer side of the light emitting structure (152). The semiconductor light emitting device (150A) may further include a passivation layer (not shown) between the light emitting structure (152) and the heat transferring insulating layer (157).

The side wiring (290) may include a first side wiring (290a) disposed on the side of the semiconductor light emitting device (150A), a second side wiring (290b) electrically contacting at least one of the first and second assembly electrodes (201, 202), and a third side wiring (290c) in contact with the assembly partition (207).

The main features of the second embodiment will be described below.

The second embodiment includes a second heat transferring insulating layer (157B) disposed on the outside of the light emitting structure (152), and the second heat transferring insulating layer (157B) can be disposed so that its lower end extends to the lower end of the light emitting structure (152).

Accordingly, the heat transferring efficiency of the second heat transferring insulating layer (157B) can be efficiently transferred to the lower edge of the semiconductor light emitting device where the first side wiring (290a) and the second side wiring (290b) meet.

For example, according to the second embodiment, the heat caused by the hot press is quickly transferred to the lower edge of the semiconductor light emitting device by the second heat transfer insulating layer (157B), thereby activating the heat diffusion of the material of the side electrode, thereby forming a solid electrode film of the first side wiring (290a) and the second side wiring (290b), thereby realizing more excellent contact characteristics.

According to the display device including the semiconductor light emitting device according to the embodiment, the electrical contact area is expanded by the side wiring connected to the side of the semiconductor light emitting device, thereby there is a technical effect that the electrical contact characteristics are improved and the lighting rate is improved.

In addition, according to the embodiment, in the side wiring technology that connects the panel wiring to the side of the light emitting device chip after self-assembly with DEP force in the internal technology, the short-circuit problem in which the side wiring is cut off at the lower edge of the light emitting device chip can be solved.

In addition, according to the embodiment, even if an electrical connection failure occurs in the bonding process of the semiconductor light emitting device (150A), a reliable electrical connection is made possible in the additional process, the hot press process, so that the lighting rate can be dramatically improved.

In addition, according to the embodiment, since a heat transferring insulating layer (157) is disposed on the outer periphery of the semiconductor light emitting device (150A) and a passivation layer is disposed between the light emitting structure (152) and the heat transferring insulating layer (157), heat or pressure in the hot press process is not directly transferred to the semiconductor light emitting device (150A), thereby preventing electrical and characteristic degradation of the light emitting structure (152).

In addition, according to the embodiment, in the case where heat is generated during display implementation in a display device equipped with a semiconductor light emitting device (150A), the heat can be diffused to the outside through the heat transferring insulating layer (157), thereby improving the reliability of the display device.

In addition, according to the embodiment, a heat transferring insulating layer (157) is disposed on the outer periphery of the semiconductor light emitting device (150A), and a part of the side electrode, for example, a first side wiring (290a), is extended and disposed not only on the light emitting structure (152) but also on the heat transferring insulating layer (157), thereby improving the bonding force between the first side wiring (290a) and the heat transferring insulating layer (157), thereby improving the reliability of the element.

In addition, according to the embodiment, the internal technology can solve the problem of the semiconductor light emitting device being detached from the assembly hole due to the weak fixing force between the semiconductor light emitting device and the dielectric layer on the assembly electrode.

The above detailed description should not be construed as restrictive in all respects, but should be considered exemplary. The scope of the embodiment should be determined by a reasonable interpretation of the appended claims, and all changes within the equivalent scope of the embodiment are included in the scope of the embodiment.

### INDUSTRIAL APPLICABILITY

The embodiment can be adopted in the field of displays that display images or information.

The embodiment can be adopted in the field of displays that display images or information using semiconductor light emitting devices.

The embodiment can be adopted in the field of displays that display images or information using micro-level or nano-level semiconductor light emitting devices.

1. A display device having a semiconductor light emitting device, comprising:
a substrate;
a first electrode and a second electrode disposed to be spaced apart from each other on the substrate;
a first insulating layer disposed on the first and second electrodes;
an assembly partition wall disposed on the first insulating layer including a predetermined assembly hole;
a semiconductor light emitting device disposed in the assembly hole;
a side wiring electrically connected to a side surface of the semiconductor light emitting device, and
a second panel electrode electrically connected to an upper surface of the semiconductor light emitting device;
wherein the semiconductor light emitting device comprises a light emitting structure and a heat transferring insulating layer disposed on an outside of the light emitting structure.

2. The display device having a semiconductor light emitting device according to claim 1, wherein the light emitting structure comprises a first conductivity type semiconductor layer, a second conductivity type semiconductor layer, and an active layer disposed therebetween, and
wherein the side wiring is electrically connected to the first conductivity type semiconductor layer of the semiconductor light emitting device.

3. The display device having a semiconductor light emitting device according to claim 1, wherein the side wiring comprises a first side wiring disposed on a side of the semiconductor light emitting device; and a second side wiring electrically contacting at least one of the first and second electrodes.

4. The display device having a semiconductor light emitting device according to claim 1, further comprises a passivation layer disposed between the light emitting structure and the heat transferring insulating layer, and
wherein a heat transferring efficiency of the passivation layer is lower than that of the heat transferring insulating layer.

5. The display device having a semiconductor light emitting device according to claim 1, wherein the side wiring is disposed on a side of the light emitting structure and the heat transferring insulating layer.

6. A display device having a semiconductor light emitting device, comprising:
a substrate;
a first electrode and a second electrode disposed spaced apart from each other on the substrate;
a first insulating layer disposed on the first and second electrodes;
an assembly partition wall having a predetermined assembly hole and disposed on the first insulating layer; and
a semiconductor light emitting device disposed in the assembly hole;
wherein the semiconductor light emitting device comprises a light emitting structure and a heat transferring insulating layer disposed on an outside of the light emitting structure, and
wherein a lower end of the heat transferring insulating layer is disposed to extend to a lower end of the light emitting structure.

7. The display device having a semiconductor light emitting device according to claim 6, wherein the light emitting structure comprises a first conductivity type semiconductor layer, a second conductivity type semiconductor layer, and an active layer disposed therebetween, and
wherein the side wiring is electrically connected to the first conductivity type semiconductor layer of the semiconductor light emitting device.

8. The display device having a semiconductor light emitting device according to claim 6, wherein the side wiring comprises a first side wiring disposed on a side of the semiconductor light emitting device; and a second side wiring electrically contacting at least one of the first and second electrodes.

9. The display device having a semiconductor light emitting device according to claim 6, further comprises a passivation layer disposed between the light emitting structure and the heat transferring insulating layer, and
wherein a heat transferring efficiency of the passivation layer is lower than that of the heat transferring insulating layer.

10. The display device having a semiconductor light emitting device according to claim 6, wherein the side wiring is disposed on a side of the light emitting structure and the heat transferring insulating layer.

11. The display device having a semiconductor light emitting device according to claim 2, further comprising a lower electrode layer disposed below the first conductivity type semiconductor layer, and
wherein a lower end of the heat transferring insulating layer is disposed on an upper end of the lower electrode layer.

12. The display device having a semiconductor light emitting device according to claim 11, wherein the side wiring is disposed on the lower electrode layer and the heat transferring insulating layer.

13. The display device having a semiconductor light emitting device according to claim 12, wherein an upper end of the side wiring is disposed higher than the lower electrode layer.

14. The display device having a semiconductor light emitting device according to claim 7, further comprising a lower electrode layer disposed below the first conductivity type semiconductor layer, and
wherein a lower end of the heat transferring insulating layer is disposed on an upper end of the lower electrode layer.

15. The display device having a semiconductor light emitting device according to claim 14, wherein the side wiring is disposed on the lower electrode layer and the heat transferring insulating layer.

16. The display device having a semiconductor light emitting device according to claim 15, wherein an upper end of the side wiring is disposed higher than the lower electrode layer.
